(19) United States
(12) Patent Application Publication
(10) Pub. No.: US 2012/0094499 A1
(43) Pub. Date: Apr. 19, 2012

(54) METHOD OF PERFORMING AN IN SITU CHAMBER CLEAN

(76) Inventors: Siu Tang Ng, Cupertino, CA (US); Guowen Ding, San Jose, CA (US); Teh-Tien Su, Milpitas, CA (US); Zhuang Li, San Jose, CA (US); Benjamin Schwarz, San Jose, CA (US); Benjamin Lee, Saratoga, CA (US)

(21) Appl. No.: 13/087,227

(22) Filed: Apr. 14, 2011

Related U.S. Application Data
(60) Provisional application No. 61/393,689, filed on Oct. 15, 2010.

(51) Int. Cl. H01L 21/3065

(52) U.S. Cl. 438/710; 257/E21.218

(57) ABSTRACT

Methods of performing in situ chamber cleaning for etch chambers are described.

### CROSS-REFERENCE TO RELATED APPLICATIONS

This application claims the benefit of U.S. Provisional Application No. 61/393,689, filed Oct. 15, 2010, the entire contents of which are hereby incorporated by reference herein.

### BACKGROUND

1) Field

Embodiments of the present invention pertain to the field of semiconductor processing and, in particular, to methods of performing in situ chamber cleaning for etch chambers.

2) Description of Related Art

Dry etching refers to the removal of material, typically a masked pattern of semiconductor material, by exposing the material to a bombardment of ions (usually a plasma of reactive gases such as fluorocarbons, oxygen, chlorine, sometimes with the addition of nitrogen, argon, helium and other gases) that chemically react with or dislodge portions of the material from the exposed surface. Unlike with many of the wet chemical etchants used in wet etching, the dry etching process typically etches directionally or anisotropically.

Dry etching is used in conjunction with photolithographic techniques to attack certain areas of a semiconductor surface in order to form recesses in material, such as contact holes (which are contacts to the underlying semiconductor substrate) or via holes (which are holes that are formed to provide an interconnect path between conductive layers in the layered semiconductor device) or to otherwise remove portions of semiconductor layers where predominantly vertical sides are desired. In conjunction with semiconductor manufacturing, micromachining and display production the removal of organic residues by oxygen plasmas is sometimes correctly described as a dry etch process. However, also the term plasma ashing may be used.

Dry etching is particularly useful for materials and semiconductors which are chemically resistant and could not be wet etched, such as silicon carbide or gallium nitride. Dry etching is currently used in semiconductor fabrication processes due to its unique ability over wet etch to do anisotropic etching (removal of material) to create high aspect ratio structures (e.g., deep via holes or capacitor trenches). The dry etching hardware design basically involves a vacuum chamber, special gas delivery system, RF waveform generator and an exhaust system.

However, significant improvements are needed in the evolution of plasma based etching processes.

### SUMMARY

Embodiments of the present invention include methods of performing in situ chamber cleaning for etch chambers.

In an embodiment, a method includes processing a semiconductor wafer in a plasma etch chamber, the processing generating a residue in the plasma etch chamber. The method also includes removing the residue with a treatment including a boron trichloride (BCl₃)-based plasma.

In another embodiment, a machine-accessible storage medium has instructions stored thereon which cause a data processing system to perform a method of performing an in situ chamber clean. The method includes processing a semiconductor wafer in a plasma etch chamber, the processing generating a residue in the plasma etch chamber. The method also includes removing the residue with a treatment including a boron trichloride (BCl₃)-based plasma.

### BRIEF DESCRIPTION OF THE DRAWINGS

FIG. 1 is a Flowchart representing operations in a method of performing an in situ chamber clean, in accordance with an embodiment of the present invention.

FIG. 2A illustrates a cross-sectional view representing an operation in a method of performing an in situ chamber clean, in accordance with an embodiment of the present invention.

FIG. 2B illustrates a cross-sectional view representing an operation in a method of performing an in situ chamber clean, in accordance with an embodiment of the present invention.

FIG. 2C illustrates a cross-sectional view representing an operation in a method of performing an in situ chamber clean, in accordance with an embodiment of the present invention.

FIG. 2D illustrates a cross-sectional view representing an operation in a method of performing an in situ chamber clean, in accordance with an embodiment of the present invention.

FIG. 2E illustrates a cross-sectional view representing an operation in a method of performing an in situ chamber clean, in accordance with an embodiment of the present invention.

FIG. 3A illustrates a cross-sectional view representing an operation in a method of processing a semiconductor wafer in a plasma etch chamber, in accordance with an embodiment of the present invention.

FIG. 3B illustrates a cross-sectional view representing an operation in a method of processing a semiconductor wafer in a plasma etch chamber, in accordance with an embodiment of the present invention.

FIG. 4A illustrates a cross-sectional view representing an operation in a method of processing a semiconductor wafer in a plasma etch chamber, in accordance with an embodiment of the present invention.

FIG. 4B illustrates a cross-sectional view representing an operation in a method of processing a semiconductor wafer in a plasma etch chamber, in accordance with an embodiment of the present invention.

FIG. 5 illustrates a block diagram of an exemplary computer system, in accordance with an embodiment of the present invention.

FIG. 6 illustrates a system in which a method of performing an in situ chamber clean is performed, in accordance with an embodiment of the present invention.

FIG. 7 is a plot representing DC bias voltage for a traditional in situ chamber clean (ICC) chemistry versus a boron trichloride (BCl₃) based ICC, in accordance with an embodiment of the present invention.

### DETAILED DESCRIPTION

Methods of performing in situ chamber cleaning for etch chambers are described. In the following description, numerous specific details are set forth, such as chemical compositions of plasma sources, in order to provide a thorough understanding of embodiments of the present invention. It will be apparent to one skilled in the art that embodiments of the present invention may be practiced without these specific details. In other instances, well-known aspects, such as photolithography patterning and development techniques for structure formation, are not described in detail in order to not unnecessarily obscure embodiments of the present invention. Furthermore, it is to be understood that the various embodiments shown in the Figures are illustrative representations and are not necessarily drawn to scale.

In embodiments of the present invention, boron trichloride (BCl₃) may be used in chamber cleaning for dry etch processes. As titanium nitride (TiN) etching, e.g., TiN hardmask etching, becomes increasingly important in semiconductor manufacturing, an in-situ chamber clean (ICC) has become an important operation for the etch process with considerations of process stability and long mean time between clean (MTBC). However, traditional ICC chemistries, such as chlorine/oxygen (Cl₂/O₂), or chlorine/oxygen/carbon tetrafluoride (Cl₂/O₂/CF₄), were found unsuitable for the TiN hardmask etch process. For example, it was found that wafer performance was shifted such that the endpoint changed and residue appeared as the number of wafers processed increased.

In-situ chamber clean has been performed conventionally with the use of fluorine chemistry for poly etch processes, and Cl₂/O₂ chemistry for Al/TiN/Ti/Ta etch processes in the semiconductor industry. However, the traditional in-situ chamber clean chemistry (such as Cl₂/O₂, or Cl₂/O₂/CF₄) for poly etch or Al etch, were found unsuitable for TiN hardmask etch, due to the process drifting. Instead, in accordance with an embodiment of the present invention, a chlorine/boron trichloride/argon (Cl₂/BCl₃/Ar) chemistry is used as a suitable solution for TiN hardmask etch processes. For example, in one embodiment, a chamber clean based on Cl₂/BCl₃/Ar provides wafer to wafer consistency and reliable productivity including particle control and MTBC extension.

It is believed that using conventional chamber clean approaches for TiN processes, the etch by-products lead to process drifting. Such by-products likely include titanium oxide (TiOₓ) which is deposited in a process chamber environment (such as a chamber wall or lid), so that the chamber environment changes with time. However, in an embodiment, a chamber clean plasma process based on the chemistry Cl₂/BCl₃/Ar is implanted in the ICC to provide a stable etching environment over the course of numerous wafer runs. It one embodiment, the Cl₂/BCl₃ aspect of the chemistry removes titanium (Ti) byproducts from the chamber wall even in the oxidized state. It is therefore effective for in situ clean of those byproducts between wafers. This effect may lead to a stable chamber wall and repeatable wafer to wafer performance. Additionally, in a specific embodiment, boron has a gathering effect for oxygen (O) and allows easier removal of components in an oxidized state. Thus, BCl₃ gas may be used for chamber cleaning involving removal of oxidized byproducts for dry etch processes. BCl₃ gas may also be used for an application using dry etch that requires removal of chamber by-products of oxidized metals or semiconductor materials, such as but not limited to, oxidized titanium (Ti), oxidized silicon (Si), or oxidized tantalum (Ta).

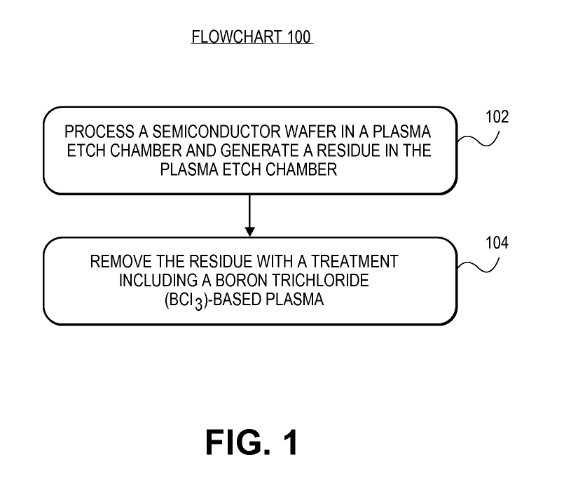

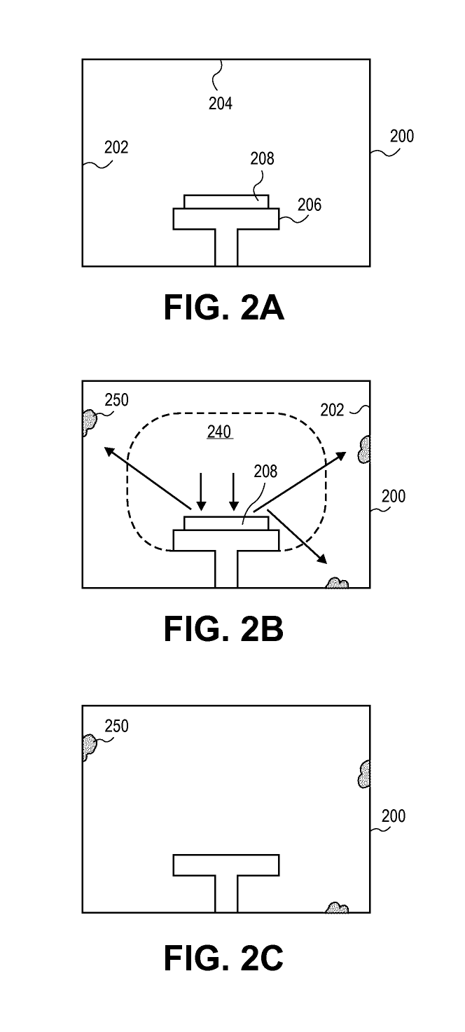

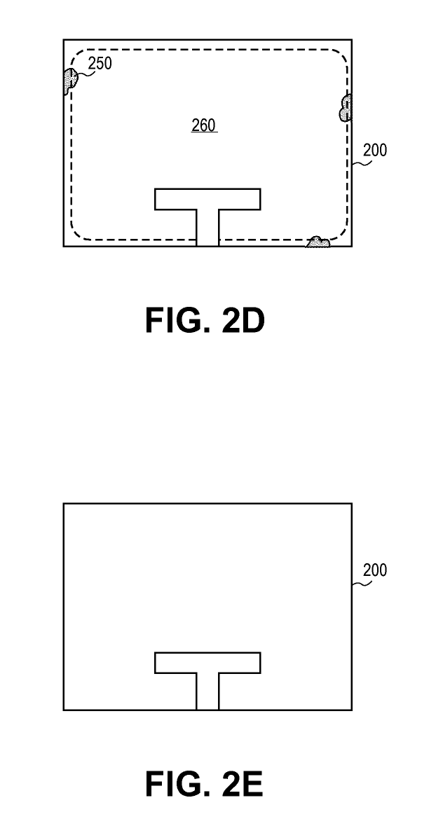

In an aspect of the present invention, a boron trichloride (BCl₃) based plasma may be used to perform an in situ chamber clean of a plasma etch chamber. For example, FIG. 1 is a Flowchart 100 representing operations in a method of performing an in situ chamber clean, in accordance with an embodiment of the present invention. FIGS. 2A-2E illustrate cross-sectional views representing operations in a method of performing an in situ chamber clean, in accordance with an embodiment of the present invention.

Referring to operation 102 of Flowchart 100 and corresponding FIG. 2A, a method of performing an in situ chamber clean includes processing a semiconductor wafer 208 in a plasma etch chamber 200. In accordance with an embodiment of the present invention, the plasma etch chamber 200 includes a chuck 206, a chamber wall 202, and a chamber lead 204, as depicted in FIG. 2A. In one embodiment, the plasma etch chamber 200 is a dual plasma source (DPS) etch chamber, such as an Applied Materials AdvantEdge DPS chamber.

Referring again to operation 102 of Flowchart 100 and corresponding FIG. 2A, the processing generates a residue 250 in the plasma etch chamber 200. In accordance with an embodiment of the present invention, the processing is performed with a chemical-based plasma 240 which bombards semiconductor wafer 208 to generate by-products such as residue 250 disposed on chamber walls 202, as depicted by the arrows in FIG. 2B. The residue 250 remains in the plasma etch chamber 200 even after completion of the processing and removal of semiconductor wafer 208 from the plasma etch chamber 200, as depicted in FIG. 2C.

In an embodiment, processing the semiconductor wafer 208 in the plasma etch chamber 200 includes etching a layer of titanium nitride (TiN), and generating the residue 250 includes forming a material composed of titanium (Ti). In one embodiment, the residue 250 is composed of titanium oxide (TiOₓ). In a specific embodiment, the layer of TiN that is etched is disposed on a silicon-containing layer, such as a layer formed from tetraethylorthosilicate (such a layer is conventionally known as a TEOS layer). In that embodiment, residue 250 also includes silicon dioxide (SiO₂).

Referring to operation 104 of Flowchart 100 and corresponding FIG. 2D, the method of performing the in situ chamber clean also includes removing the residue 250 from the plasma etch chamber 200 with a treatment comprising a boron trichloride (BCl₃)-based plasma 260. In accordance with an embodiment of the present invention, the treatment is performed in the absence of a wafer or substrate in the plasma etch chamber 200, as depicted in FIG. 2D. Referring to FIG. 2E, the treatment leaves the plasma etch chamber 200 entirely or essentially free from residue 250. In one embodiment, the chamber clean process provided a clean chamber for run to run uniformity.

In an embodiment, the boron trichloride (BCl₃)-based plasma 260 is a plasma formed from the gases boron trichloride (BCl₃), chlorine (Cl₂), and argon (Ar). In one embodiment, the boron trichloride (BCl₃)-based plasma 260 does not include fluorine (F) or bromine (Br) species since by-products of the type TiFₓ or TiBrₓ are non-volatile. In one embodiment, the ratio of boron trichloride (BCl₃):chlorine (Cl₂):argon (Ar) is approximately 1:2:2.

In an embodiment, removing the residue 250 with the treatment includes applying the boron trichloride (BCl₃)-based plasma 260 for a duration approximately in the range of 20 seconds-30 seconds. In an embodiment, the boron trichloride (BCl₃)-based plasma 260 is a plasma having a pressure approximately in the range of 4 milliTorr-60 milliTorr. In one embodiment, the boron trichloride (BCl₃)-based plasma 260 has a first, initial pressure of approximately 8 milliTorr and has a second, final pressure of approximately 50 milliTorr.

In an embodiment, the temperature of the chuck 206 is approximately 40 degrees Celsius, the temperature of the chamber wall 202 is approximately in the range of 65-80 degrees Celsius, and the temperature of the chamber lead 204 is approximately in the range of 65-120 degrees Celsius during the treatment with the boron trichloride (BCl₃)-based plasma 260. In one such embodiment, the boron trichloride (BCl₃)-based plasma 260 is a plasma formed from the gases boron trichloride (BCl₃), chlorine (Cl₂), and argon (Ar), wherein the ratio of boron trichloride (BCl₃):chlorine (Cl₂):argon (Ar) is approximately 1:2:2. In that embodiment, the boron trichloride (BCl₃)-based plasma 260 is applied for a duration approximately in the range of 20 seconds-30 seconds and has a pressure approximately in the range of 4 milliTorr-60 milliTorr.

In an embodiment, processing the semiconductor wafer 208 in the plasma etch chamber 200 includes etching with an oxygen (O₂)-based plasma free of boron (B), and removing the residue 250 with the treatment of the boron trichloride (BCl₃)-based plasma 260 includes using an oxygen (O₂)-free plasma. In one embodiment, O₂ and BCl₃ are not mixed at either of the processing or chamber clean operations since the combination of O₂ and BCl₃ is too reactive and may otherwise damage semiconductor wafer 208 or plasma etch chamber 200.

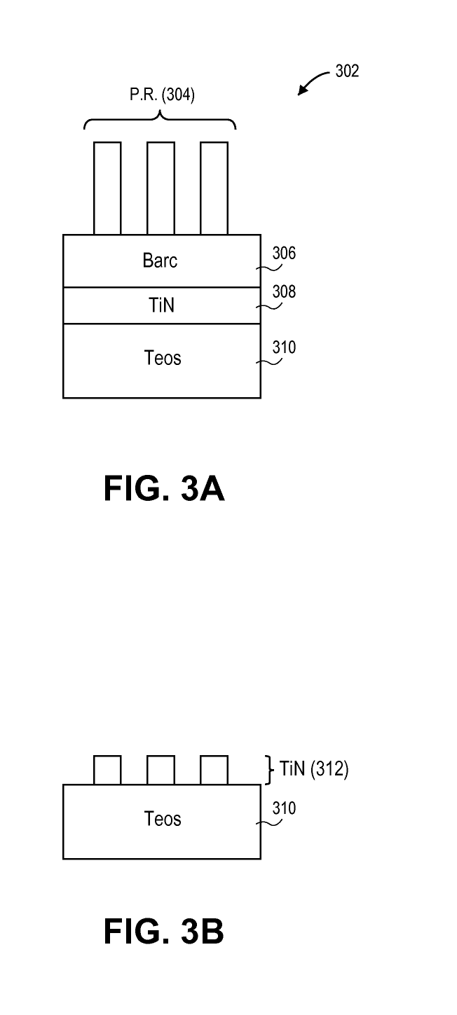

A semiconductor stack including a layer of titanium nitride (TiN) may be processed, generating a residue requiring removal during an in situ chamber clean process based on a boron trichloride (BCl₃) plasma. For example, FIGS. 3A and 3B illustrate cross-sectional views representing operations in a method of processing a semiconductor wafer in a plasma etch chamber, in accordance with an embodiment of the present invention.

Referring to FIG. 3A, a semiconductor stack 302 includes a patterned layer of photo-resist 304 (P.R.) disposed on a bottom anti-reflective coating layer 306 (Barc layer) disposed on a titanium nitride layer 308 (TiN) disposed on a layer formed from tertraethylorthosilicate 310 (TEOS layer). Referring to FIG. 3B, the pattern of photo-resist layer 304 is transferred to the titanium nitride layer 308 by etching semiconductor stack 302 with one or more plasma etch processes to provide a patterned titanium nitride layer 312. In an embodiment, titanium-containing residue is formed on the chamber walls of an etch chamber during the etching.

The photo-resist layer 304 may be composed of a material suitable for use in a lithographic process. That is, in an embodiment, the photo-resist material is exposed to a light source and subsequently developed to provide photo-resist layer 304. In one embodiment, the portions of the photo-resist material to be exposed to the light source will be removed upon developing the photo-resist material, e.g., the photo-resist layer 304 is composed of a positive photo-resist material. In a specific embodiment, the photo-resist layer 304 is composed of a positive photo-resist material such as, but not limited to, a 248 nm resist, a 193 nm resist, a 157 nm resist, an extreme ultra-violet (EUV) resist, or a phenolic resin matrix with a diazonaphthoquinone sensitizer. In another embodiment, the portions of the photo-resist material to be exposed to the light source will be retained upon developing the photo-resist material, e.g., the photo-resist layer 304 is composed of a negative photo-resist material. In a specific embodiment, the photo-resist layer 304 is composed of a negative photo-resist material such as, but not limited to, poly-cis-isoprene and poly-vinyl-cinnamate.

Semiconductor stack 302 may further include a substrate upon which layers 304, 306, 308 and 310 are disposed. The substrate may be composed of a material suitable to withstand a fabrication process and upon which semiconductor processing layers may suitably reside. In accordance with an embodiment of the present invention, the substrate is composed of a group IV-based material such as, but not limited to, crystalline silicon, germanium or silicon/germanium. In a specific embodiment, providing the substrate includes providing a monocrystalline silicon substrate. In a particular embodiment, the monocrystalline silicon substrate is doped with impurity atoms. In another embodiment, the substrate is composed of a III-V material.

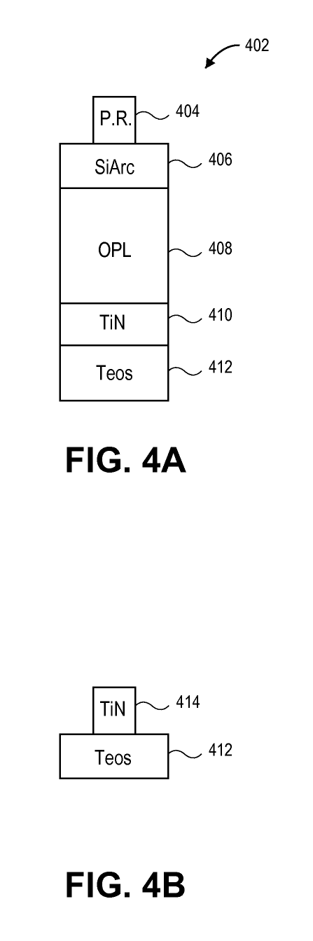

FIGS. 4A and 4B illustrate cross-sectional views representing operations in a method of processing another semiconductor wafer in a plasma etch chamber, in accordance with an embodiment of the present invention.

Referring to FIG. 4A, a semiconductor stack 402 includes a patterned layer of photo-resist 404 (P.R.) disposed on a silicon anti-reflective coating layer 406 (SiArc) disposed on a resist-like OPL layer 408 (OPL) disposed on a titanium nitride layer 410 (TiN) disposed on a layer formed from tertraethylorthosilicate 412 (TEOS layer). Referring to FIG. 4B, the pattern of photo-resist layer 404 is transferred to the titanium nitride layer 410 by etching semiconductor stack 402 with one or more plasma etch processes to provide a patterned titanium nitride layer 414. In an embodiment, titanium-containing residue is formed on the chamber walls of an etch chamber during the etching.

Embodiments of the present invention may be provided as a computer program product, or software, that may include a machine-readable medium having stored thereon instructions, which may be used to program a computer system (or other electronic devices) to perform a process according to the present invention. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., carrier waves, infrared signals, digital signals, etc.)), etc.

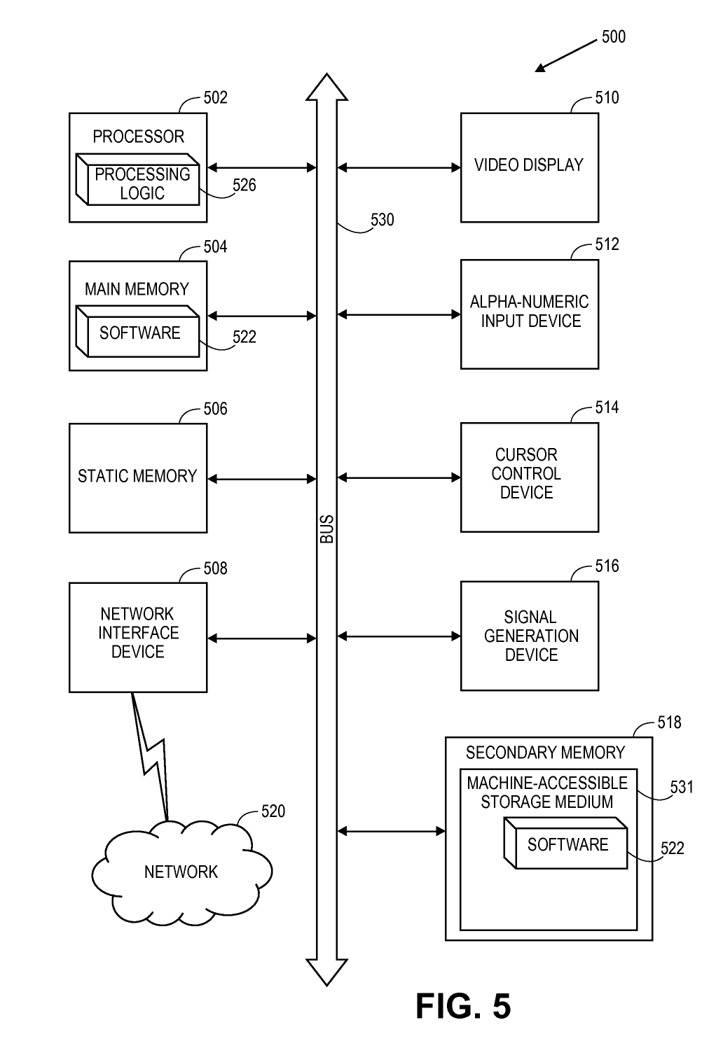

FIG. 5 illustrates a diagrammatic representation of a machine in the exemplary form of a computer system 500 within which a set of instructions, for causing the machine to perform any one or more of the methodologies discussed herein, may be executed. In alternative embodiments, the machine may be connected (e.g., networked) to other machines in a Local Area Network (LAN), an intranet, an extranet, or the Internet. The machine may operate in the capacity of a server or a client machine in a client-server network environment, or as a peer machine in a peer-to-peer (or distributed) network environment. The machine may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated, the term “machine” shall also be taken to include any collection of machines (e.g., computers) that individually or jointly execute a set (or multiple sets) of instructions to perform any one or more of the methodologies discussed herein.

The exemplary computer system 500 includes a processor 502, a main memory 504 (e.g., read-only memory (ROM), flash memory, dynamic random access memory (DRAM) such as synchronous DRAM (SDRAM) or Rambus DRAM (RDRAM), etc.), a static memory 506 (e.g., flash memory, static random access memory (SRAM), etc.), and a secondary memory 518 (e.g., a data storage device), which communicate with each other via a bus 530.

Processor 502 represents one or more general-purpose processing devices such as a microprocessor, central processing unit, or the like. More particularly, the processor 502 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processor 502 may also be one or more special-purpose processing devices such as an application specific integrated circuit (ASIC), a field programmable gate array (FPGA), a digital signal processor (DSP), network processor, or the like. Processor 502 is configured to execute the processing logic 526 for performing the operations discussed herein.

The computer system 500 may further include a network interface device 508. The computer system 500 also may include a video display unit 510 (e.g., a liquid crystal display (LCD) or a cathode ray tube (CRT)), an alphanumeric input device 512 (e.g., a keyboard), a cursor control device 514 (e.g., a mouse), and a signal generation device 516 (e.g., a speaker).

The secondary memory 518 may include a machine-accessible storage medium (or more specifically a computer-readable storage medium) 531 on which is stored one or more sets of instructions (e.g., software 522) embodying any one or more of the methodologies or functions described herein. The software 522 may also reside, completely or at least partially, within the main memory 504 and/or within the processor 502 during execution thereof by the computer system 500, the main memory 504 and the processor 502 also constituting machine-readable storage media. The software 522 may further be transmitted or received over a network 520 via the network interface device 508.

While the machine-accessible storage medium 531 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies of the present invention. The term “machine-readable storage medium” shall accordingly be taken to include, but not be limited to, solid-state memories, and optical and magnetic media.

In accordance with an embodiment of the present invention, a machine-accessible storage medium has instructions stored thereon which cause a data processing system to perform a method of performing an in situ chamber clean. The method includes processing a semiconductor wafer in a plasma etch chamber, the processing generating a residue in the plasma etch chamber. The method also includes removing the residue with a treatment of a boron trichloride (BCl₃)-based plasma.

In an embodiment, processing the semiconductor wafer in the plasma etch chamber includes etching a layer of titanium nitride (TiN), and generating the residue includes forming a material composed of titanium (Ti). In an embodiment, processing the semiconductor wafer in the plasma etch chamber includes etching with an oxygen (O₂)-based plasma free of boron (B), and removing the residue with the treatment of the boron trichloride (BCl₃)-based plasma includes using an oxygen (O₂)-free plasma. In an embodiment, the plasma etch chamber is a dual plasma source (DPS) etch chamber.

In an embodiment, the boron trichloride (BCl₃)-based plasma is a plasma formed from the gases boron trichloride (BCl₃), chlorine (Cl₂), and argon (Ar). In one embodiment, the ratio of boron trichloride (BCl₃):chlorine (Cl₂):argon (Ar) is approximately 1:2:2. In an embodiment, removing the residue with the treatment includes applying the boron trichloride (BCl₃)-based plasma for a duration approximately in the range of 20 seconds-30 seconds. In an embodiment, the boron trichloride (BCl₃)-based plasma is a plasma having a pressure approximately in the range of 4 milliTorr-60 milliTorr. In one embodiment, the boron trichloride (BCl₃)-based plasma has a first, initial pressure of approximately 8 milliTorr and has a second, final pressure of approximately 50 milliTorr. In an embodiment, the plasma etch chamber includes a chuck, a chamber wall, and a chamber lead, and the temperature of the chuck is approximately 40 degrees Celsius, the temperature of the chamber wall is approximately in the range of 65-80 degrees Celsius, and the temperature of the chamber lead is approximately in the range of 65-120 degrees Celsius during the treatment with the boron trichloride (BCl₃)-based plasma. In one such embodiment, the boron trichloride (BCl₃)-based plasma is a plasma formed from the gases boron trichloride (BCl₃), chlorine (Cl₂), and argon (Ar), the ratio of boron trichloride (BCl₃):chlorine (Cl₂):argon (Ar) is approximately 1:2:2, the boron trichloride (BCl₃)-based plasma is applied for a duration approximately in the range of 20 seconds-30 seconds, and the boron trichloride (BCl₃)-based plasma is a plasma having a pressure approximately in the range of 4 milliTorr-60 milliTorr.

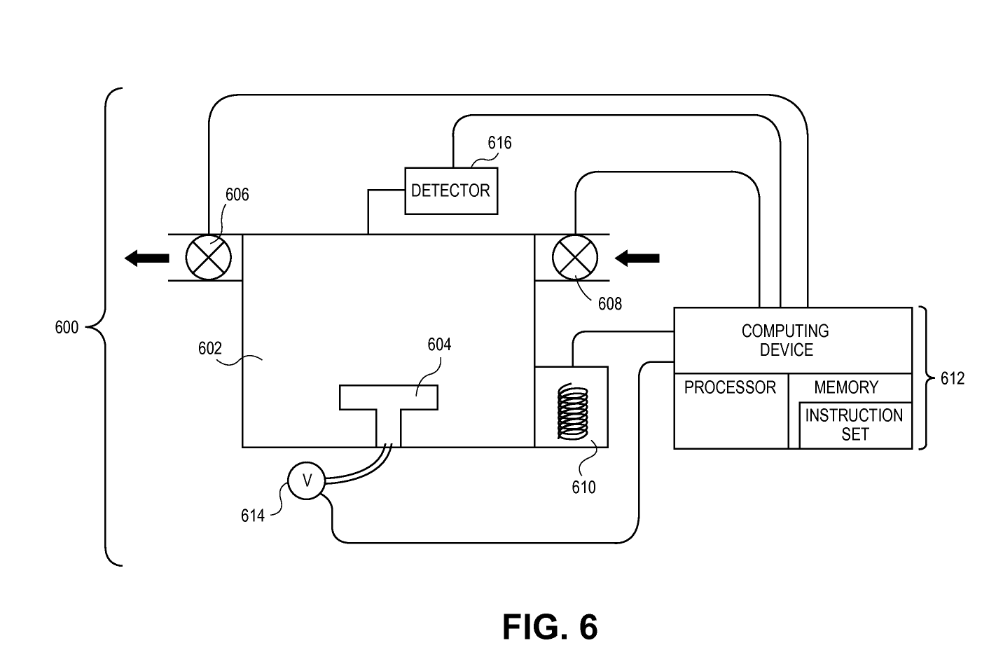

An in situ chamber clean process may be conducted in processing equipment suitable to provide an etch plasma in proximity to a sample for etching. For example, FIG. 6 illustrates a system in which a method of performing an in situ chamber clean is performed, in accordance with an embodiment of the present invention.

Referring to FIG. 6, a system 600 for conducting a plasma etch process includes a chamber 602 equipped with a sample holder 604. An evacuation device 606, a gas inlet device 608 and a plasma ignition device 610 are coupled with chamber 602. A computing device 612 is coupled with plasma ignition device 610. System 600 may additionally include a voltage source 614 coupled with sample holder 604 and a detector 616 coupled with chamber 602. Computing device 612 may also be coupled with evacuation device 606, gas inlet device 608, voltage source 614 and detector 616, as depicted in FIG. 6.

Chamber 602 and sample holder 604 may include a reaction chamber and sample positioning device suitable to contain an ionized gas, i.e. a plasma, and bring a sample in proximity to the ionized gas or charged species ejected therefrom. Evacuation device 606 may be a device suitable to evacuate and de-pressurize chamber 602. Gas inlet device 608 may be a device suitable to inject a reaction gas into chamber 602. Plasma ignition device 610 may be a device suitable for igniting a plasma derived from the reaction gas injected into chamber 602 by gas inlet device 608. Detection device 616 may be a device suitable to detect an end-point of a processing step. In one embodiment, system 600 includes a chamber 602, a sample holder 604, an evacuation device 606, a gas inlet device 608, a plasma ignition device 610 and a detector 616 similar to, or the same as, those included in an Applied Materials™ AdvantEdge G3 etcher.

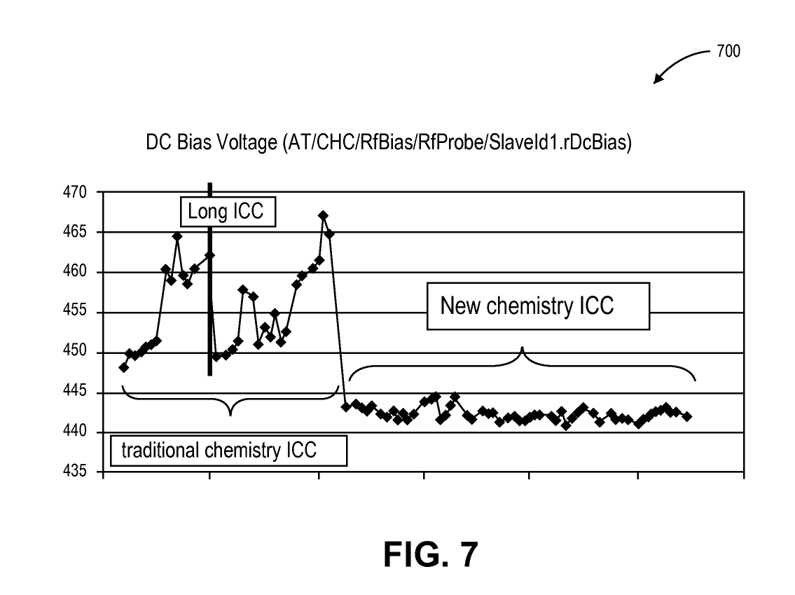

FIG. 7 is a plot 700 representing DC bias voltage for a traditional in situ chamber clean (ICC) chemistry versus a boron trichloride (BCl₃) based ICC, in accordance with an embodiment of the present invention. Referring to plot 700, when the ICC chemistry is changed to Cl₂/BCl₃/Ar, the wafer performance is very stable. During a TiN etch process, the by-product of Ti readily becomes TiOₓ, which is deposited in a chamber. The Cl₂/BCl₃ chemically reacts with Ti/TiOₓ to remove Ti by-products from the chamber wall. In one embodiment, such an approach provides a stable chamber wall and repeatable wafer to wafer performance in the corresponding etch chamber. In one embodiment, boron of the BCl₃ has a gathering effect for oxygen and allows easier removal of oxygen-containing components or residues in the oxidized state.

Thus, methods of performing in situ chamber cleaning for etch chambers have been disclosed. In accordance with an embodiment of the present invention, a method includes processing a semiconductor wafer in a plasma etch chamber. The processing generates a residue in the plasma etch chamber. The residue is removed with a treatment using a boron trichloride (BCl₃)-based plasma. In one embodiment, processing the semiconductor wafer in the plasma etch chamber includes etching a layer of titanium nitride (TiN), and generating the residue includes forming a material comprising titanium (Ti). In one embodiment, processing the semiconductor wafer in the plasma etch chamber includes etching with an oxygen (O₂)-based plasma free of boron (B), and removing the residue with the treatment of the boron trichloride (BCl₃)-based plasma includes using an oxygen (O₂)-free plasma.

What is claimed is:

1. A method of performing an in situ chamber clean, the method comprising:
processing a semiconductor wafer in a plasma etch chamber, the processing generating a residue in the plasma etch chamber; and
removing the residue with a treatment comprising a boron trichloride (BCl₃)-based plasma.

2. The method of claim 1, wherein processing the semiconductor wafer in the plasma etch chamber comprises etching a layer of titanium nitride (TiN), and generating the residue comprises forming a material comprising titanium (Ti).

3. The method of claim 1, wherein processing the semiconductor wafer in the plasma etch chamber comprises etching with an oxygen (O₂)-based plasma free of boron (B), and wherein removing the residue with the treatment comprising the boron trichloride (BCl₃)-based plasma comprises using an oxygen (O₂)-free plasma.

4. The method of claim 1, wherein the boron trichloride (BCl₃)-based plasma is a plasma formed from the gases boron trichloride (BCl₃), chlorine (Cl₂), and argon (Ar).

5. The method of claim 4, wherein the ratio of boron trichloride (BCl₃):chlorine (Cl₂):argon (Ar) is approximately 1:2:2.

6. The method of claim 1, wherein removing the residue with the treatment comprises applying the boron trichloride (BCl₃)-based plasma for a duration approximately in the range of 20 seconds-30 seconds.

7. The method of claim 1, wherein the boron trichloride (BCl₃)-based plasma is a plasma having a pressure approximately in the range of 4 milliTorr-60 milliTorr.

8. The method of claim 7, wherein the boron trichloride (BCl₃)-based plasma has a first, initial pressure of approximately 8 milliTorr and has a second, final pressure of approximately 50 milliTorr.

9. The method of claim 1, wherein the plasma etch chamber comprises a chuck, a chamber wall, and a chamber lead, and wherein the temperature of the chuck is approximately 40 degrees Celsius, the temperature of the chamber wall is approximately in the range of 65-80 degrees Celsius, and the temperature of the chamber lead is approximately in the range of 65-120 degrees Celsius during the treatment with the boron trichloride (BCl₃)-based plasma.

10. The method of claim 9, wherein the boron trichloride (BCl₃)-based plasma is a plasma formed from the gases boron trichloride (BCl₃), chlorine (Cl₂), and argon (Ar), wherein the ratio of boron trichloride (BCl₃):chlorine (Cl₂):argon (Ar) is approximately 1:2:2, wherein the boron trichloride (BCl₃)-based plasma is applied for a duration approximately in the range of 20 seconds-30 seconds, and wherein the boron trichloride (BCl₃)-based plasma is a plasma having a pressure approximately in the range of 4 milliTorr-60 milliTorr.

11. The method of claim 1, wherein the plasma etch chamber is a dual plasma source (DPS) etch chamber.

12. A machine-accessible storage medium having instructions stored thereon which cause a data processing system to perform a method of performing an in situ chamber clean, the method comprising:
processing a semiconductor wafer in a plasma etch chamber, the processing generating a residue in the plasma etch chamber; and
removing the residue with a treatment comprising a boron trichloride (BCl₃)-based plasma.

13. The storage medium as in claim 12, wherein processing the semiconductor wafer in the plasma etch chamber comprises etching a layer of titanium nitride (TiN), and generating the residue comprises forming a material comprising titanium (Ti).

14. The storage medium as in claim 12, wherein processing the semiconductor wafer in the plasma etch chamber comprises etching with an oxygen (O₂)-based plasma free of boron (B), and wherein removing the residue with the treatment comprising the boron trichloride (BCl₃)-based plasma comprises using an oxygen (O₂)-free plasma.

15. The storage medium as in claim 12, wherein the boron trichloride (BCl₃)-based plasma is a plasma formed from the gases boron trichloride (BCl₃), chlorine (Cl₂), and argon (Ar).

16. The storage medium as in claim 15, wherein the ratio of boron trichloride (BCl₃):chlorine (Cl₂):argon (Ar) is approximately 1:2:2.

17. The storage medium as in claim 12, wherein removing the residue with the treatment comprises applying the boron trichloride (BCl₃)-based plasma for a duration approximately in the range of 20 seconds-30 seconds.

18. The storage medium as in claim 12, wherein the boron trichloride (BCl₃)-based plasma is a plasma having a pressure approximately in the range of 4 milliTorr-60 milliTorr.

19. The storage medium as in claim 18, wherein the boron trichloride (BCl₃)-based plasma has a first, initial pressure of approximately 8 milliTorr and has a second, final pressure of approximately 50 milliTorr.

20. The storage medium as in claim 12, wherein the plasma etch chamber comprises a chuck, a chamber wall, and a chamber lead, and wherein the temperature of the chuck is approximately 40 degrees Celsius, the temperature of the chamber wall is approximately in the range of 65-80 degrees Celsius, and the temperature of the chamber lead is approximately in the range of 65-120 degrees Celsius during the treatment with the boron trichloride (BCl₃)-based plasma.

21. The storage medium as in claim 20, wherein the boron trichloride (BCl₃)-based plasma is a plasma formed from the gases boron trichloride (BCl₃), chlorine (Cl₂), and argon (Ar), wherein the ratio of boron trichloride (BCl₃):chlorine (Cl₂):argon (Ar) is approximately 1:2:2, wherein the boron trichloride (BCl₃)-based plasma is applied for a duration approximately in the range of 20 seconds-30 seconds, and wherein the boron trichloride (BCl₃)-based plasma is a plasma having a pressure approximately in the range of 4 milliTorr-60 milliTorr.

22. The storage medium as in claim 12, wherein the plasma etch chamber is a dual plasma source (DPS) etch chamber.
